(19) United States
(12) Patent Application Publication
(10) Pub. No.: US 2005/0249254 A1
(43) Pub. Date: Nov. 10, 2005

(54) Current-confinement heterostructure for an epitaxial mode-confined vertical cavity surface emitting laser

(76) Inventor: Dennis G. Deppe, Austin, TX (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 11/105,782

(22) Filed: Apr. 13, 2005

Related U.S. Application Data
(60) Provisional application No. 60/562,567, filed on Apr. 14, 2004.

(51) Int. Cl. H01S 5/00

(52) U.S. Cl. 372/46.01; 372/19; 372/99

(57) ABSTRACT

A vertical-cavity surface-emitting laser comprises one or more semiconductor epitaxial phase-shifting mesa layers that are adapted to provide optical mode confinement, and that are further embedded between semiconductor epitaxial materials with a conductivity type that is substantially the same as the phase-shifting mesa layers. The laser further includes reverse-biased p-n junction materials adjacent to the epitaxial phase-shifting mesa layers that laterally confine electrically injected current to the phase-shifting mesa layers through formation of resistive material outside the phase-shifting mesa layers.

### RELATED APPLICATION

This application claims the benefit of U.S. Provisional Application No. 60/562,567, filed Apr. 14, 2004, which provisional application is incorporated by reference herein in its entirety.

### TECHNICAL FIELD

The disclosed embodiments relate generally to solid-state optoelectronics devices, and more particularly to semiconductor vertical cavity surface emitting lasers.

### BACKGROUND

A vertical cavity surface emitting laser (VCSEL) can be formed from epitaxial semiconductor mirrors to create a very compact, low optical loss, all-semiconductor microcavity. The VCSEL has become an important laser device since it can operate efficiently at low power levels with good beam characteristics, and is relatively easy to manufacture. VCSELs have applications as fiber optic sources and in sensing, as well as for bar code scanners, compact disk storage, displays, solid state lighting, and others. In a VCSEL a GaAs substrate is often used on which AlxGa1-xAs/AlyGa1-yAs distributed Bragg reflecting (DBR) mirrors and active materials are grown using single crystal epitaxy. Other semiconducting or nonsemiconducting substrates, such as InP or sapphire, can be used with different active materials to create VCSELs that operate over a wide range of wavelengths. These active materials may include InGaN for ultraviolet and blue emission, InGaAlP for visible light emission between 600 nm to 700 nm, AlGaAs for light emission in the 700 nm to 850 nm range, GaAs for emission in the 800 to 880 nm range, InGaAs for emission in the 900 nm to 1.2 μm range, and InGaNAs for emission in the 1.1 μm to 1.6 μm wavelength range. Novel combinations of these materials, including their nanostructures (quantum wires or quantum dots), can also be used to obtain even greater wavelength emission ranges for a given VCSEL substrate and mirror material. For example, planar layers of GaInNAs or GaAsSb, or InGaAs nanostructures can be used to obtain 1.3 μm emission in AlGaAs based VCSELs, and nanostructures of InGaNAs may be used to obtain even longer wavelengths extending beyond 1.6 μm.

VCSELs generally use conducting materials within the cavity to excite the optically active material. Generally, semiconductor materials conduct p- and n-type charge to inject electrons and holes into the active material and obtain light emission, with the conducting materials being placed between the two mirrors of the cavity, or with the mirrors themselves forming the conducting materials. The two mirrors that are made normal to the crystal surface and form the vertical cavity are generally made from DBRs formed from alternating semiconductor layers with different refractive indices. The use of conducting mirrors can lead to a very compact, small volume light source that is readily excited with electrical current injection and operates with relatively high efficiency.

In order to reduce the operating current, improve the efficiency, and improve the speed of the VCSEL, it is highly desirable to laterally confine the optical mode and the injected electrical current to nearly the same device area. Although this simultaneous electrical and optical confinement can be obtained by simply etching a pillar, this approach leads to optical scattering and therefore increased optical loss as the size of the pillar is reduced. The increasing optical loss with reducing pillar size then also leads to an increasing threshold current density with reducing pillar size. If no lateral confinement exists, and the lasing mode is only confined due to the formation of a gain region, diffraction loss degrades the VCSEL performance through increasing the lasing threshold which in turn reduces the operating speed. Therefore obtaining very low optical loss in the VCSEL mode is important to achieving high speed and high performance.

A native oxide layer may also be selectively formed in the VCSEL cavity, and this oxide layer can simultaneously confine both the optical mode and the electrical injection current. Native-oxide-confined VCSELs can obtain much high modulation speed than gain-guided VCSELs because of the elimination of diffraction loss and reduction in threshold current. However, this native oxide layer is typically formed by a timed oxidation process of high Al content AlGaAs, and the lateral extent of the oxide layer depends critically on the oxidation time, Al content, and oxidation conditions. Therefore while the oxide aperture leads to simultaneous confinement of both the optical mode and the electrical current injection path, and does so with very low optical loss, the process suffers from poor reproducibility and controllability.

In addition, the native oxide causes a device reliability problem. This is because the oxide has a different thermal expansion coefficient than the surrounding semiconductor material of the VCSEL, and despite lower power consumption the strain it creates inside the device can lead to early device failure. This reliability problem requires that the oxide be placed at nonoptimal distances from the active region to reduce the strain effects in the active region, with a degradation in device performance.

Another limitation is that the native oxide process has thus far proven effective only for AlxGa1-xAs, while other materials are also desirable for VCSELs that operate at wavelengths not accessible to the GaAs/AlGaAs materials used for VCSEL mirrors. It has not proven useful for InP-based VCSELs, or nitride-based VCSELs, or other non-AlGaAs materials, despite the commercial importance of these other materials.

Thus, the art of semiconductor lasers, although producing various methods to form VCSELs, recognizes a need for a VCSEL that can obtain very low optical loss in its mode confinement to give low threshold and high efficiency, and be fabricated with a high reproducibility across a wafer and from wafer to wafer, that is absent of mechanical strain and lateral size variation due to external process parameters.

### SUMMARY

The disclosed embodiments are directed to VCSELs that use intracavity epitaxial phase-shifting mesa layers to laterally confine an optical mode, and that use conductivity change in the surrounding layers to direct current flow through the phase-shifting layer. Using these embodiments optical confinement and current confinement can be achieved in the same crystal region with the optical mode achieving very low optical loss. The phase-shifting layer is designed for low optical scattering loss through both the degree of phase-shift it introduces into the cavity relative to the region outside the phase-shifting layer and its placement in the cavity.

In some embodiments the phase-shifting mesa layers are placed within a current confining epitaxial recessed region of high electrical resistance. The recessed region lies outside the intracavity phase-shifting layer and serves to strongly confine the electrical current flow and can also be used to identify the position of the phase-shifting layer.

It is among the advantages of the disclosed embodiments that the optical mode confining phase-shifting region and current confining recessed region can be self-aligned in a single epitaxial step to increase the effectiveness of the electrical confinement, while maintaining low optical loss. It is also among the advantages of the present invention that mode confining region can be portioned into closely spaced phase-shifting mesa layers of same or differing lateral sizes in order to control the transverse modal behavior of the VCSEL. For example, stable multimode operation can be forced by the phase-shifting mesa layers using various individual mesa sizes in a densely packed array, or single mode may be obtained by carefully choosing the mesa sizes and array pattern.

### BRIEF DESCRIPTION OF THE FIGURES

FIG. 1 shows a schematic cross-section diagram of an embodiment of a VCSEL, with shallow phase-shifting mesa layers that laterally confine the optical mode. These phase-shifting mesa layers are formed in a recessed region formed from a larger diameter aperture. The area outside the recessed region is rendered highly resistive to electrical current through either doping changes that create reverse biased p-n junctions, or semi-insulating semiconductor. The semi-insulating semiconductor can be formed by controlling the growth conditions to induce Fermi level pinning defects or through introducing impurities that create deep levels to pin the Fermi level within the energy gap. In some cases the recessed region outside the phase-shifting mesa layers may also be made conducting to current, while only the area outside the larger diameter aperture is made to block current. This may be desirable, for one example, when the phase-shifting mesa layers are formed in a close packed array to control the lateral optical mode. However, the recessed region may also be made highly resistive to current flow by using properly doped regions to form one or more reverse biased p-n junctions adjacent to the phase-shifting mesa layers, while the phase-shifting mesa layers alone forms the conducting channel.

FIG. 2 shows a schematic cross-section diagram of an embodiment of a VCSEL, again with shallow phase-shifting mesa layers to confine the optical mode. In this case layers outside the phase-shifting mesa layers are doped to create one or more reverse biased p-n junctions outside the mode confined region that are highly resistive to current flow. The layers within the phase-shifting mesa layers have doping levels adjusted to provide a low resistance conductive path through the mesa.

FIG. 3 shows a schematic cross-section diagram of an embodiment of a VCSEL, again with phase-shifting mesa layers formed on the crystal surface to confine the optical mode. In contrast to the layer structure of FIG. 2, the phase-shifting mesa layers and the region outside the phase-shifting mesa layers are chosen with different materials to enable potentially absorbing materials to be removed from the cavity, except for a thin layer placed at a node of the standing wave lasing field within the phase-shifting mesa layers.

FIG. 4 shows an energy band diagram of the region off the phase-shifting mesa layers in FIGS. 2 and 3 that are doped to be highly resistive to current flow. The highly resistive region is formed by heavily n-doping a thin crystal layer in the upper DBR, around a region of the DBR that is otherwise doped p-type. The n-doping and p-doping layers are chosen to form a significant barrier. The energy band diagram is for an AlGaAs/GaAs VCSEL.

FIG. 5 shows an energy band diagram of the region of the phase-shifting mesa layers. The thin heavily n-doped layer is compensated in the region of the phase-shifting mesa layers by the more heavily p-doped layer just above it. The conversion of this n-doped layer to p-type by modulation doping provides the high electrical conductivity through the phase-shifting mesa layers.

FIG. 6 shows a top plan view drawing of a VCSEL corresponding to the illustration of FIG. 1. In this VCSEL the area 191 of FIG. 1 exists outside a ring (shown as dashed lines) that is 15 μm outer diameter in the actual device. Region 190 encompasses the phase-shifting mesa layers of 192, with the phase-shifting mesa layers of 192 having a diameter of 7 μm. The actual VCSEL does not contain the n-type blocking layer in region 191 of FIG. 1, so that current is passed through the entire 15 μm diameter area that includes cavity regions 190 and 192. A Cr/Au ring electrode is placed on region 191 well away from region 190.

FIG. 7 shows a light vs. current curve for the 7 μm diameter mesa confined VCSEL of FIG. 6.

FIG. 8 (a) shows spontaneous emission from the 7 μm phase-shifting mesa layers with the lowest order mode at ˜972 nm and a spectral separation of 1 nm to the next higher order transverse mode of the phase-shifting mesa layers. Emission from the outer 15 μm ring region is at 965 nm. (b) shows lasing from the 7 μm phase-shifting mesa layers above the total injected current of 1.3 mA. (c) shows lasing from the 7 μm phase-shifting mesa layers (˜970 to 972 nm) and 15 μm outer ring region (966 nm) above 5 mA current.

FIG. 9 Top view looking down at examples of two-dimensional patterns with the shaded regions corresponding to the cavity regions of 192 of FIG. 1 that contain the phase-shifting mesa layers. (a) shows a triangular lattice of off-phase-shifting mesa layer holes. (b) shows a circular grating that can be designed to match a Bessel function mode for sizes greater than ˜2 μm or a lens for ring sizes <<1 μm (assuming ˜0.98 μm). (c) shows a PC defect.

### DETAILED DESCRIPTION OF EMBODIMENTS

The embodiments are described herein with reference to a series of examples of VCSELs that use intracavity shallow epitaxial phase-shifting mesa layers in the semiconductor cavity. The electrical current is confined to the phase-shifting mesa layers by forming highly resistive epitaxial regions outside the phase-shifting mesa. These highly resistive regions are formed from reversed biased p-n junctions adjacent to the phase-shifting mesa regions, and can include epitaxial semi-insulating semiconductor layers, or combinations of p-n junctions and semi-insulating semiconductor layers outside etched recessed regions that contain the phase-shifting mesa and mode confining regions.

While the height of the phase-shifting mesa layers is a critical parameter in determining the optical loss associated with scattering from the step created by the phase-shifting mesa layers, the height of additional highly resistive layers outside the phase-shifting mesa layers can be placed far enough away to have no impact on the optical loss of the VCSEL. The additional layers outside the phase-shifting mesa layers can be made highly resistive by including additional reverse-biased p-n junctions that block the current, or epitaxial semi-insulating layers formed from either low temperature grown epitaxial material, implantation of impurities that form deep levels, or epitaxially grown material containing impurities that form deep levels. The semi-insulating layers are due to pinning of the crystal's Fermi level in these regions within the semiconductor's energy gap.

The current can be additionally confined to the same shallow phase-shifting mesa layers that confine the optical field. This additional current confinement can be achieved through use of a modulation doping technique. In this case a thin layer heavily doped with donor impurities is formed directly under the phase-shifting mesa layers. The phase-shifting mesa layers that exist on top of the layer heavily doped with donors is doped sufficiently heavily p-type to transfer some of its hole charge to the donor-doped material, thereby converting the donor-doped material to p-type through modulation doping. Where the phase-shifting mesa layers are absent the heavily donor-doped material remains uncompensated and n-type forming a barrier for hole flow.

Alternatively, the phase-shifting mesa layers can contain p-doping at sufficient level that a high temperature anneal can be made to diffuse p-type impurity atoms from the phase-shifting mesa layers into the donor-doped crystal region immediately below it, and thus directly convert this region to p-type conductivity through introduction of p-type impurity atoms.

Therefore a relatively low resistance path for current flow through the phase-shifting mesa layers may be formed while obtaining a relatively high resistance path for current flow outside the phase-shifting mesa layers by controlling the placement and concentration of impurity atoms so as to form p-type conductivity in the region through and below the phase-shifting mesa layers, while forming n-type conductivity materials in regions outside the phase-shifting mesa layers. In this way electrical current is directed into the VCSEL region also containing the means for optically confining the lasing mode with low optical loss.

These two techniques, the etched recess region containing highly resistive regions due to either reverse-biased or semi-insulating semiconductor, and reverse biased p-n junction regions formed outside the phase-shifting mesa layers through control of doping within and beneath the phase-shifting mesa layers, can be combined to provide very strong electrical confinement to the phase-shifting mesa layers so that electrical current passes only through the mode-confined region. The electrical current can then be confined to the phase-shifting mesa layers even for a device with electrode placement that covers a much larger area than the phase-shifting mesa layers. In this way the thickness of the additional layers outside the phase-shifting mesa layers that provide stronger current blocking also can function as optical alignment markers for additional lithography steps that follow in the VCSEL fabrication.

These current confinement schemes can also be used with phase-shifting mesa layers that are patterned into various shapes, for example to form an intracavity 1-dimensional or 2-dimensional photonic crystal or grating pattern with the VCSEL's lasing mode area, thus affecting the lateral mode of the VCSEL. Either or both current confinement schemes can be employed with the intracavity photonic crystal or grating.

### EXAMPLE 1

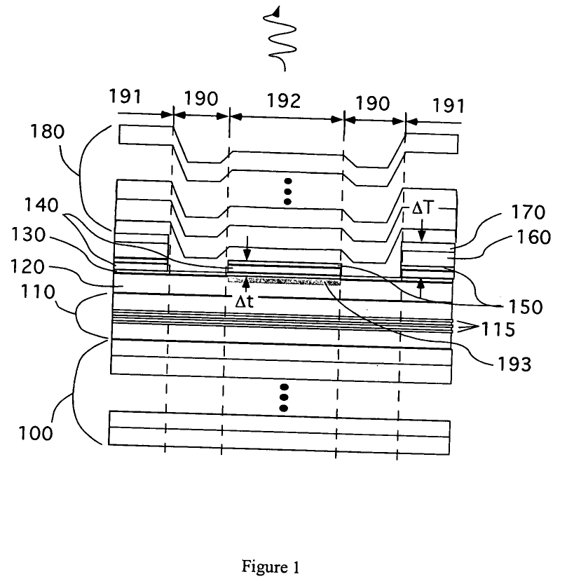

Reference is first made to FIG. 1. Collectively, the layers 100 form a lower DBR. In some embodiments, the layers include alternating dielectric layers made from different semiconductor materials that can be grown on a semiconductor substrate. Other nonsemiconducting alternating dielectric layers may also be used, or their reflectivities may be enhanced with metal reflectors. A semiconducting active material, either bulk semiconductor, planar quantum wells, quantum wires, or quantum dots are placed in a cavity spacer forming layers 110 that contain one or more active layers 115. The upper DBR is patterned to form three distinct cavity regions, 190, 191, and 192. The lasing mode is confined in cavity region 192 formed by the phase-shifting mesa layers, with the mode confinement due to a resonance shift in the vertical cavity formed by the step height Δt between cavity region 192 and cavity region 190. For mode confinement it is not necessary that the crystal layers above layer 150 be formed to retain the precise shape of the phase-shifting layers 150 and 140, but that only an optical resonance shift be obtained between cavity regions 190 and 192 of sufficient magnitude relative to the lateral size of cavity region 192. Cavity region 190 laterally encloses region 192, and both cavity regions may have a wide range of lateral shape designs. The third cavity region is 191 that encloses cavity region 190 creating a step height between cavity region 190 and 192 of ΔT. The purpose of cavity region 191 is to create a region well outside the optical mode of the VCSEL that provides a highly resistive layer for electrical current flow even for a large area of cavity 191. In some embodiments, electrodes can be placed in cavity region 191 for electrical contacting, with the electrical current routed to cavity region 190 and cavity region 192. In addition, the electrodes may also overlap cavity region 190. However, some optical scattering will occur if the electrodes are placed too close to cavity region 192, unless the electrode covers cavity region 192 and is designed as a reflectivity enhancing layer.

In some embodiments, the electrical current may be further confined to only cavity region 192 by choice of dopants in layers 120, 130, 150, and 180. The mode confined in cavity region 192 will possess an evanescent tail in cavity region 190. This tail is the decaying part of the confined mode that extends some distance into cavity region 190, but with exponentially decreasing field amplitude. In order to obtain the lowest optical loss for the mode confined in cavity region 192, the cavity region 190 should have a lateral dimension sufficient to minimize the overlap of the evanescent tail into region 191. Or, cavity region 190 may be carefully designed to obtain mode selectivity favoring lowest order transverse mode lasing by providing greater optical loss to higher order transverse modes confined to the phase-shifting mesa layers 140 and 150.

Because the height of the phase-shifting mesa layers 140, 150, can be designed for low optical loss by providing only sufficient resonance shift to confine the optical mode, without introducing excess scattering due to a large change in the fields between cavity regions 190 and 192, a second purpose of cavity region 191 is to create a clearly defined marker to identify the cavity regions 190 and 192 for subsequent lithography steps after the formation of these layers, and therefore provide easy optical alignment. This can significantly improve the yield of the fabrication steps.

In FIG. 1, layer 120 is a p-doped mirror layer of the upper DBR. Additional DBR mirror layers may also be fabricated between layers 120 and the cavity spacer layers 110 that contain one or more active layers 115. However there can be an advantage in obtaining low threshold current by keeping current confining layers 130 and 140 above layer 120 as close as possible to the cavity spacer region layers 110. The cavity spacer region layers 110 may include doping, especially with p-doping above the active layers, to aid in current confinement. Layer 130 allows lateral definition of the phase-shifting mesa layers 140 and 150 in the cavity region 192 from where light emission occurs. Layers 160 and 170 form the highly electrically resistive layers that block current from passing through cavity region 191, and can also provide a significant step height to serve as a marker for identification of the cavity regions 190 and 192 to simplify device fabrication and electrode placement. This step height, marked ΔT in FIG. 1, can be much greater than the step height of the phase-shifting mesa layers due to layers 140 and 150, and marked Δt in FIG. 1. While Δt is chosen sufficiently large to provide optical confinement, but sufficiently small to avoid scattering loss, ΔT has little impact on the optical loss and can therefore be chosen conveniently large to facilitate high yield device fabrication and easy optical alignment.

Layers 160 and 170 can be made highly resistive by at least two methods. In the first method, reverse biased p-n junctions are formed by doping either layer 160 or layer 170, or both, n-type. When a forward bias is applied through electrodes made to cavity region 191 the current can then be forced into cavity regions 190 and 192, even given a large area for cavity region 191 on which the metal electrodes are formed. A second method is to form either layer 160 or 170 from semi-insulating semiconductor, either through controlling the growth and annealing of these layers to introduce deep defect levels and thus obtain Fermi level pinning near mid-gap, or through incorporation of deep level impurities that create Fermi level pinning near mid-gap.

Another means of forming current blocking layers in cavity region 191 is through implantation of either shallow impurities into layers 160 and 170, and possibly the regions below, to form reverse biased p-n junctions, or through implantation of deep level impurities to cause Fermi level pinning near mid-gap in these levels.

Layers 130, 140, and 150 can be either p-doped to pass current through cavity regions 190 and 192, or contain further current blocking layers. In some cases, for example when the phase-shifting mesa layers in region 192 are fabricated in the form of a 2-D array or grating, it may be desirable to electrically inject into both cavity regions 190 and 192 to obtain high power and influence the optical coupling between the regions containing the phase-shifting mesa layers. For other applications though, for example for low threshold VCSELs, it may be an advantage to pass current only through the phase-shifting mesa layers 140 and 150 in cavity region 192.

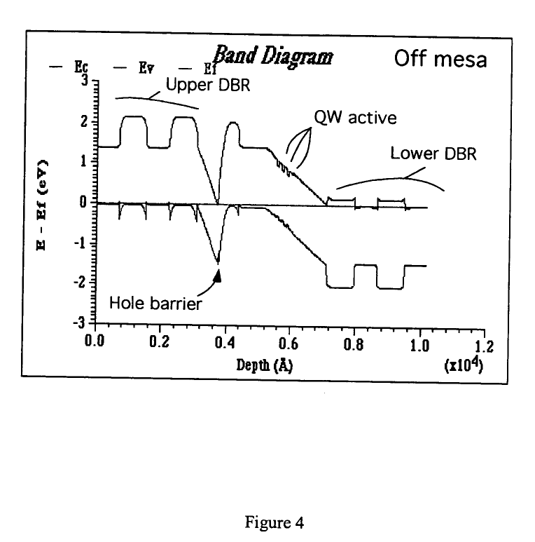

Current can be confined to pass only through cavity region 192 containing the phase-shifting mesa layers by further controlling the doping in layers 130, 140, and 150 to create a barrier to hole flow in cavity region 190 while passing holes easily through cavity region 192. This can be obtained by doping the layers of 130, which may further contain heterobarriers, sufficiently n-type such that a potential barrier is formed in the valence band between the DBR mirror layers 180 in the region just adjacent to layer 130 and layer 120 in cavity region 190. The size of this potential barrier in cavity region 190 for given doping levels in layers 120, 130, and 180, and any possible p-doping introduced into layers 110, is analyzed below with results presented in FIG. 4. The size of the barrier depends on the doping impurity levels, and the heterobarrier design. Heterobarriers may be used to form layers 130, for example, to offset effects of Fermi level pinning that may occur due to defects introduced in the interfacial regions between layers 130 and 180 in cavity region 190.

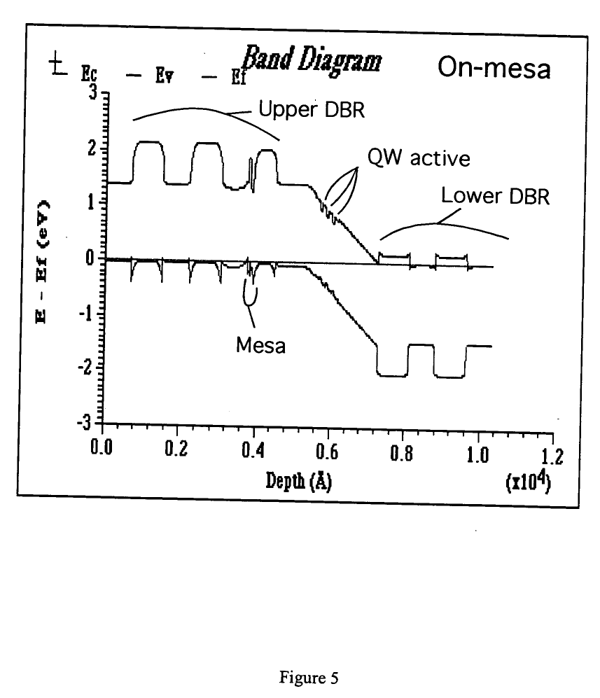

Two methods can be used to obtain a low resistance current path through the phase shifting mesa region layers 130, 140, and 150, in cavity region 192 through removal of the hole barrier in the region cavity 192 alone. Along with sufficient n-doping of layers 130, layer 140 and possibly layer 150 in cavity region 192 are sufficiently p-doped to create hole transport and compensation in layers 130 in the region 193 that include layers 130, to eliminate or reduce the potential barrier for hole flow in cavity region 192. This doping scheme, based on modulation doping, can be most effective when the layers 120, 130, and 140 are chosen to obtain a small energy gap and the proper band discontinuities in layer 130 relative to layers 120 and 140. Doping levels needed in layers 120, 130, 140, 150, and 180 for removal of the potential barrier for hole flow in cavity region 192 are analyzed with results presented in FIG. 5 below.

Alternatively, the phase-shifting mesa layers of 140 and 150 may contain p-type impurities of sufficient concentration that after removal of layers 140 and 150 in cavity region 190, an anneal is performed to diffuse excess p-type impurity atoms into cavity layers 130 thereby directly converting them to p-type conductivity through the selective introduction of p-type impurity atoms. In this case layers 140 and 150 can be used as a p-type impurity diffusion source to form the low electrical resistance path 193 in cavity region 192.

### EXAMPLE 2

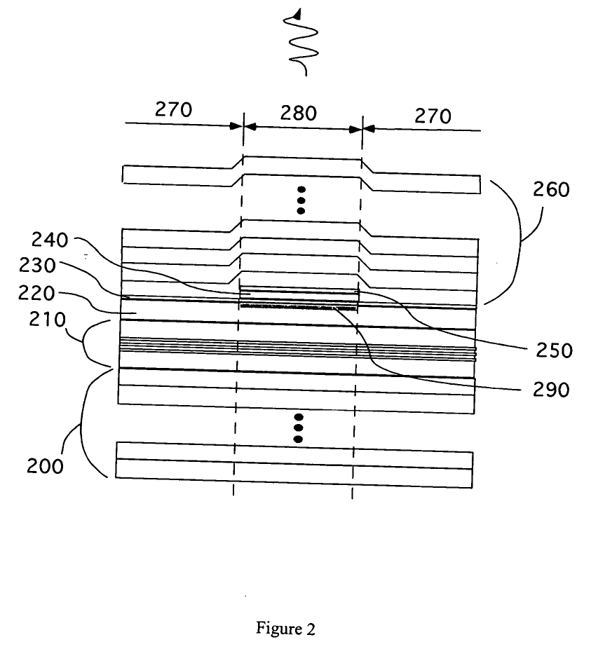

FIG. 2 shows an embodiment of the invention that includes two cavity regions, 270 and 280. In such a scheme it is possible to obtain current blocking by appropriate doping choices in layers 220, 230, 240, 250, and 260, and possibly in the cavity spacer region 210, such that a potential barrier is formed for hole flow in cavity region 270 while passing current in cavity region 280 using the techniques described in Example 1. In such an embodiment the degree of electrical current confinement to cavity region 280 may be sacrificed in favor of simpler fabrication, or the mode-confining region 280 may be relatively large with respect to region 270 that additional current confinement layers are not needed. Layers 220 and 260 are doped p-type, and layers in 230, which may contain heterobarriers, are doped sufficiently n-type to obtain a potential barrier to hole flow in cavity spacer region 270. The upper cavity spacer layers 210 may also be doped p-type to aid in barrier formation. Layers 240 and 250 are doped sufficiently p-type to compensate the n-doping in 230 so that it contains excess holes in cavity region 280. In this doping scheme it can be an advantage for layers 230 to have a smaller energy gap than layers 220 and 240 with proper band discontinuities to aid in hole collection in layers 230 from the p-doped layers 240 and 250. In this embodiment additional impurities or deep level defect species may be implanted into part of the cavity region 270 to further confine the electrical current to the cavity region 280. The key is to obtain the low resistance electrical path through the phase-shifting mesa layers and cavity region 280 by reducing the potential barrier for hole flow in region 290 relative to that laterally outside region 290 in cavity region 270. This is accomplished by the creation of the hole barrier in layers 230 in cavity region 290.

### EXAMPLE 3

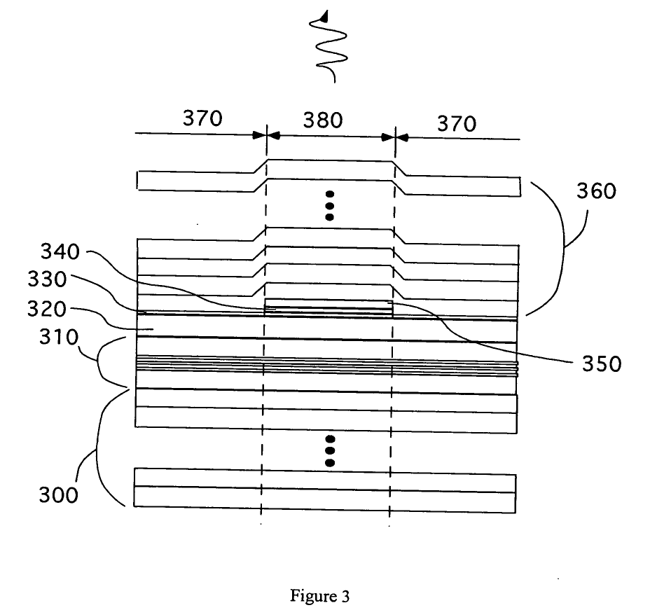

FIG. 3 shows another embodiment. In some cases it can be an advantage to include materials in the embodiment that provide high etch selectivity for fabrication of phase-shifting mesa layers outside an epitaxial growth chamber prior to a second epitaxial growth, but which may then be removed through selective etching inside the growth chamber through either thermal etching or a combination of thermal and gas etching. For example, GaAs can be thermally etched under As overpressure at temperatures greater than 600° C., while AlGaAs layers are etched at a very slow rate for temperatures less than 750° C. It's also the case that gas etches such as CBr4 etch GaAs layers at a much higher rate than AlGaAs layers, and therefore can also be used for in-situ selective etching in an epitaxial growth chamber. These in-situ etching processes can be useful to eliminate surface contaminants from the crystal, or to remove protective layers that might otherwise degrade VCSEL performance if left in the optical cavity.

In FIG. 3 layers 320 and 360 are doped p-type, and layers 330 contain n-type doping at the proper levels so as to create a barrier for hole flow in cavity region 370. Layer 340 is a thin layer added to allow etch definition of the phase-shifting mesa layers forming cavity region 380, but which is desired to be removed along with any protective layers above layer 350 once the structure is reintroduced into an epitaxial growth chamber. Layer 340 and any protective layers covering layer 350 are then removed in-situ in a second epitaxial growth step. This fabrication approach can be attractive when the materials forming layers 330 and 350 may otherwise be subject to oxide formation or surface contamination during fabrication steps that hinder high quality epitiaxial growth of the layers 360. This is true, for example, if layers 330 and 350 are AlGaAs, since Al bearing III-V compounds form an oxide that is difficult to remove. It may also be attractive if protective layers are used to cover 350 that are then subject to Fermi level pinning defects, but that can be removed by etch techniques that are used in-situ in the crystal growth system prior to second epitaxial growth. This approach is also useful to fully eliminate surface contaminants that are otherwise difficult to remove from protective layers that may cover layer 350.

### POTENTIAL BARRIER FORMATION AND ITS ELIMINATION THROUGH MODULATION DOPING TO OBTAIN ELECTRICAL CURRENT CONFINEMENT

FIG. 4 shows an equilibrium band diagram calculated from a choice of doping levels needed to create a significant potential barrier to hole flow in the cavity spacer regions 190 of FIG. 1, 270 of FIG. 2, or 370 of FIG. 3 for a given AlGaAs/GaAs heterostructure system. In FIG. 4 the Fermi level is taken as the zero of energy for the vertical axis. Similar results can be obtained in other III-V materials through proper choice of materials and doping levels. Notably, InP-based materials or GaN-based materials are also attractive for obtaining this current confinement mechanism. While the band diagram shown in FIG. 4 is specific to the layer structure of FIG. 1, these results can be extended to the layer structures of FIG. 2 or FIG. 3 following the same design approach. The layers are chosen for a 980 nm VCSEL design.

FIG. 4 shows an equilibrium band diagram that includes part of the DBR layers 100, a cavity spacer region 110 containing three InGaAs quantum wells placed at the center, layers 120 and 130 above this cavity spacer, and the lower part of the upper DBR layers in 180. The band diagram is calculated for cavity region 190 with layers consisting of a lower AlAs/GaAs DBR forming layers 100 that are doped uniformly n-type with a donor concentration of 5×1017 cm-3, an active layer spacer 110 that includes Al0.05Ga0.95As that includes at its center a GaAs/InGaAs active region of three InGaAs quantum wells 60 Å thick each clad by GaAs barriers of 100 Å thickness, and the upper cavity region. The Al0.05Ga0.95As layers on either side of the GaAs/InGaAs quantum well active layer are 1067 Å thick. The upper 947 Å part of the includes Al0.05Ga0.95As cavity spacer region 110 is doped lightly with acceptor impurities at a level of 5×1017 cm-3. Layer 120 consists of Al0.7Ga0.3As of thickness 566 Å doped with acceptors at a level of 2×1018 cm-3. Layer 130 consists of GaAs of thickness 75 Å doped with donor impurities at a level of 1×1019 cm-3. The lowest layer of the DBR mirror 180 is GaAs of thickness 625 Å doped with acceptors at a level of 5×1017 cm-3. The remaining layers of DBR 180 above this are quarter wave layers of AlAs thickness 830 Å and GaAs thickness 700 Å doped uniformly with acceptors at a level of 2×1018 cm-3. Grading at the interfaces and acceptor doping variations are common in order to reduce the electrical resistance through the p-type mirrors. These grading and doping variations will not impact the current confinement mechanism of the embodiment.

The band diagram of FIG. 4 shows a potential barrier of approximately 1.4 eV, the energy gap of GaAs, formed in the valence band of the layered structure at the position of 0.38 μm on the horizontal axis in FIG. 4. This 1.4 eV barrier is created by the n-type impurities introduced in layer 130 of FIG. 1. The doping levels in the crystal regions of layers 110, 120, and 180 that surround 130 are sufficiently low so as to create this barrier for hole flow. The energy band diagram of FIG. 4 is that of a p-n-p-n device that will contain both forward bias and reverse biased p-n junctions when a positive bias is applied to mirror layers 180 relative to mirror layers 100 through external electrodes. Negligible current flow occurs up to ˜4 V bias, at which point p-n-p-n switching behavior is observed with a hysteresis loop. Therefore this p-n-p-n blocking region can prevent current flow in cavity regions 190 under VCSEL operation.

FIG. 5 shows the band diagram calculated for the phase shifting mesa layers of 192 in FIG. 1. The doping and layer thicknesses are the same in FIG. 4 for all layers common to regions 190 and 192. However, cavity region 192 also contains additional layers 140 and 150. In cavity region 192 layer 140 consists of Al0.7Ga0.3As of thickness 50 Å doped with acceptors at a level of 2×1019 cm-3. This doping level can be achieved with Zn, Be, Mg, or C acceptors, but C is preferable to prevent diffusion of acceptor impurities at a relatively high doping level in Al0.7Ga0.3As. Layer 150 consists of GaAs of thickness 75 Å doped with acceptor impurities at a level of 1×1019 cm-3. Layers 140 and 150 are designated as the phase-shifting mesa layers in FIG. 5. The band structure of FIG. 5 shows that the heavily doped layers 140 and 150 eliminate the electrons above the cavity spacer in layer 130 due to the donor impurities. Therefore, the phase-shifting mesa layers are fully p-type, providing easy hole flow and low electrical resistance into the cavity spacer region 110. There is no p-n-p-n band structure in cavity region 192 do to the additional layers 140 and 150 in this region.

As mentioned above, the potential barrier for hole flow outside the phase-shifting mesa layers may also be removed by inclusion of excess p-type impurities in the phase-shifting mesa layers, which are then caused to diffuse under annealing into the layers beneath the phase-shifting mesa layers containing n-type impurities and thereby directly converting these layers to p-type conductivity.

This invention therefore provides electrical current flow only through cavity region 192 in FIG. 1, while blocking current flow in cavity region 190. Because the holes flow through the cavity region 192 with low resistance, cavity region 192 prevents a sufficient bias from forming over cavity region 190 that might otherwise cause current flow through the p-n-p-n structure in region 190.

### VERIFICATION OF MODE CONFINEMENT

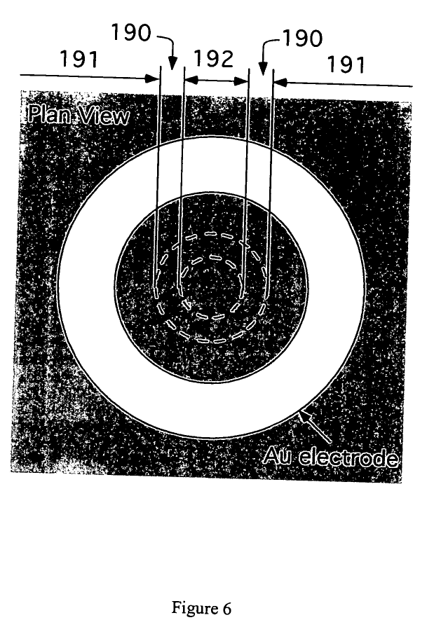

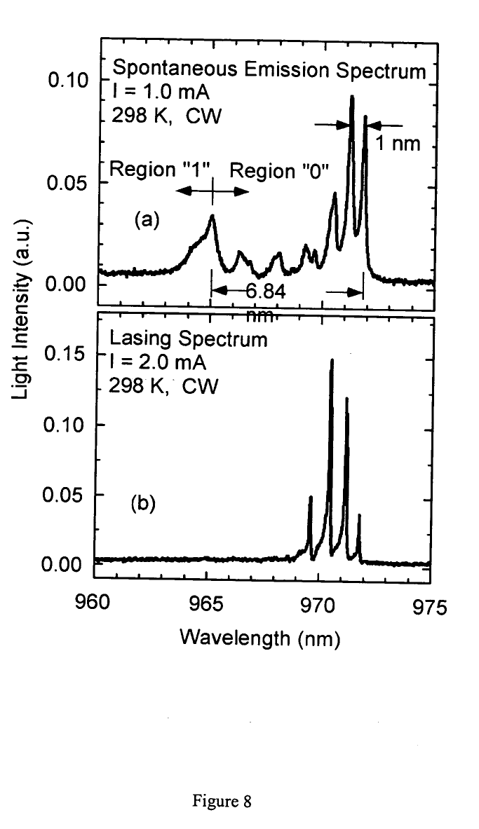

The mode confinement has been verified using epitaxial crystal growth and the embodiment as shown in FIG. 1 with layer 130 doped p-type (no p-n-p-n blocking region). In this way current is blocked in region 191 of FIG. 1, but passed through regions 190 and 192 to characterize the optical emission from these regions. FIG. 6 is an illustration drawn from the perspective of looking down on the crystal surface of a VCSEL with 7 μm diameter phase-shifting mesa layers forming the cavity region 192 of FIG. 1. The phase-shifting mesa layers are created by a very shallow step on the crystal surface Δt designed (both height and placement) to give low optical loss and good optical mode confinement. The larger outer ring is 15 μm in diameter and is used as a marker to identify the active region position for metallization. Electrode formation on the crystal surface is Cr and Au, and Ge/Au alloy is used to contact an n-type GaAs substrate on which the VCSEL is grown. The influence of the phase-shifting mesa layers and the region around the phase-shifting mesa layers can be seen in the VCSEL's spectral emission shown in FIG. 8.

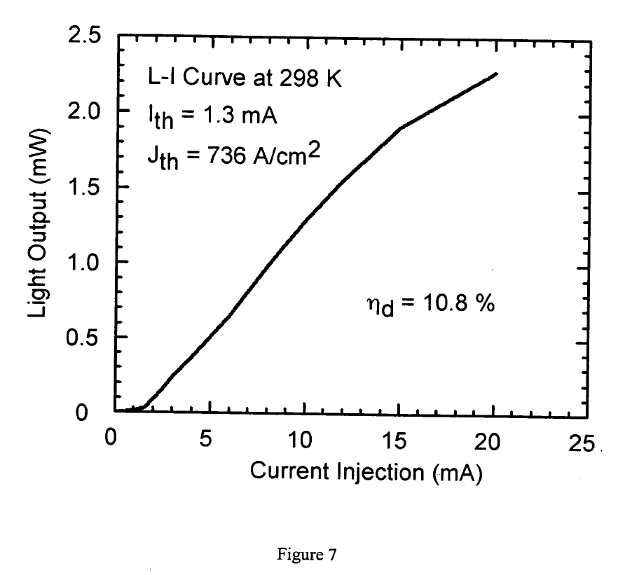

The light versus current curve for this device is shown in FIG. 7 and demonstrates a low threshold current of 1.3 mA despite the current that flows in cavity regions 190 and 192 due to the lack of p-n-p-n blocking in region 190. By analyzing the current voltage characteristics as well as light emission from around the phase-shifting mesa layers we determine that only 30% of the injected current goes through the cavity region 192. Thus the true threshold current through the phase-shifting mesa layers is only 360 μA. Similarly the efficiency is ˜12% because of the current passing through region 190.

FIG. 8 shows the VCSEL's spectral characteristics. The spectral scans have different horizontal scales. (a) shows the spectral emission below threshold, (b) shows the emission just above with lasing due to the phase-shifting mesa layers, and (c) shows the spectral emission well above threshold where lasing occurs not only from the phase-shifting mesa layers but also from the region outside the phase-shifting mesa layers (in the ring formed by the 15 μm diameter outer boundary and the 7 μm phase-shifting mesa layers, layer 190 of FIG. 1). The 1 nm mode spacings in the spontaneous emission of (a) of ˜972 nm are due to the 7 μm diameter mesa. The emission from the ring region with the outer 15 μm diameter boundary at 965 nm is shifted to shorter wavelength (higher frequency) due to the cavity resonance shift in this region corresponding to region 190 of FIG. 1. The shift in spectral emission between cavity regions containing the 7 μm phase-shifting mesa layers (region 192 in FIG. 1) and the outer ring within the 15 μm diameter of FIG. 6 (region 190 of FIG. 1), along with mode separation in FIG. 8 (a) demonstrate that the optical field is confined in the 7 μm diameter phase-shifting mesa layers.

### GRATINGS AND INTRACAVITY PHOTONIC CRYSTALS

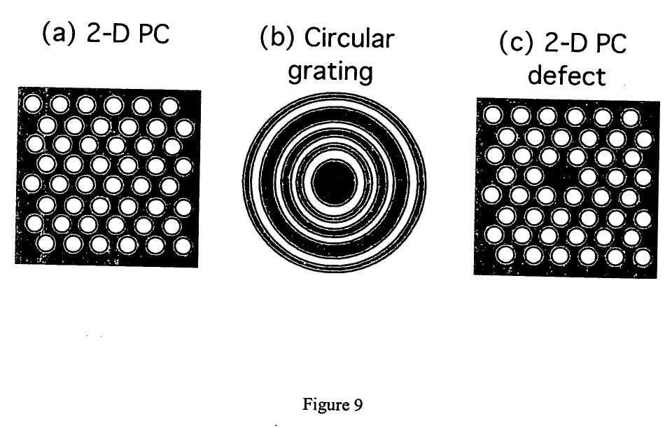

The phase-shifting mesa layers can be patterned into gratings or 2-dimensional photonic crystal patterns, to form an array or pattern of cavity regions 192. FIG. 9 shows examples of gratings that can be included in the VCSEL cavity based on the present embodiments and is not an exhaustive list. The shaded regions in FIG. 9 refer to the cavity regions 192 in FIG. 1, which are the phase-shifting mesa layers. FIG. 9 (a) shows a 2-D PC. This structure will introduce energy gaps into the VCSEL's optical mode spectrum and include band edges. The 2-D PC can eliminate undesirable transverse wavevector components. Highly multimode operation can also be generated by increasing the dimensions of FIG. 9 (a) so that the phase-shifting mesa layers are 1 μm in diameter or greater, approximately the smallest mode dimension possible for a single mode confining region formed from the phase-shifting mesa layers. FIG. 9 (b) is of interest in two different regimes. For relatively large dimensions the circular grating can be matched to the lowest order Bessel function, and selective electrical injection into the shaded regions combined with the mode confinement can enhance its optical overlap relative to higher order modes. For dimensions much less than the lateral wavevector component the circular grating becomes a lens, and can be chirped to precisely tailor the lateral mode profile and reduce optical loss. FIG. 9 (c) shows a 2-D PC defect mode to improve transverse mode selectivity.

1. A vertical-cavity surface-emitting laser comprising:
one or more semiconductor epitaxial phase-shifting mesa layers adapted to provide optical mode confinement embedded between semiconductor epitaxial materials with a conductivity type that is substantially the same as the phase-shifting mesa layers; and
reverse-biased p-n junction materials adjacent to the epitaxial phase-shifting mesa layers that laterally confine electrically injected current to the phase-shifting mesa layers through formation of resistive material outside the phase-shifting mesa layers.

2. The vertical-cavity surface-emitting laser of claim 1, further comprising:
a recessed region having the phase-shifting mesa layers and reverse-biased p-n junctions formed therein; and
an outer region outside the recessed region that is resistive to electrical current flow.

3. The vertical-cavity surface-emitting laser of claim 1, further comprising:
embedding epitaxial layers including the epitaxial phase-shifting mesa layers, wherein the conductivity of the epitaxial phase-shifting mesa layers and the embedding epitaxial layers are made substantially similar through modulation doping of the phase-shifting mesa layers to a level sufficient that the modulation doping occurs in the embedding epitaxial layers and provides conductivity in the embedding epitaxial layers having the same polarity as the conductivity in the phase-shifting mesa layers.

4. The vertical-cavity surface-emitting laser of claim 3, further comprising:
a recessed region having the phase-shifting mesa layers and reverse-biased p-n junctions formed therein; and
an outer region outside the recessed region that is resistive to electrical current flow.

5. The vertical-cavity surface-emitting laser of claim 1, further comprising:
embedding epitaxial layers including epitaxial phase-shifting mesa layers, wherein the conductivity of the epitaxial phase-shifting mesa layers and the embedding epitaxial layers are made substantially similar through impurity doping of the phase-shifting mesa layers such that the impurity doping atoms diffuse into the embedding epitaxial layers, causing the embedding epitaxial layers to have conductivity substantially the same as the phase-shifting mesa layers.

6. The vertical-cavity surface-emitting laser of claim 5, further comprising:
a recessed region having the phase-shifting mesa layers and reverse-biased p-n junctions formed therein; and
an outer region outside the recessed region that is resistive to electrical current flow.

7. The vertical-cavity surface-emitting laser of claim 1, wherein the phase-shifting mesa layers include mesas of varying sizes.

8. The vertical-cavity surface-emitting laser of claim 1, wherein the phase-shifting mesa layers include mesas arranged in a densely packed array.

9. The vertical-cavity surface-emitting laser of claim 1, wherein the phase-shifting mesa layers have a height selected to provide sufficient resonance shift to confine the optical mode without introducing excess scattering.

10. The vertical-cavity surface-emitting laser of claim 1, wherein at least one phase-shifting mesa layer is doped to provide a conductive path through at least one mesa in the phase-shifting mesa layers.

11. A method of forming a vertical-cavity surface-emitting laser, comprising:
forming one or more semiconductor epitaxial phase-shifting mesa layers between one or more layers of semiconductor epitaxial materials; and
forming reverse-biased p-n junction materials adjacent to the epitaxial phase-shifting mesa layers for laterally confining electrically injected current to the phase-shifting mesa layers through formation of resistive material outside the phase-shifting layers.
